(19) United States
(12) Patent Application Publication
(10) Pub. No.: US 2018/0151301 A1
(43) Pub. Date: May 31, 2018

(54) EPITAXIAL PEROVSKITE MATERIALS FOR OPTOELECTRONICS

(71) Applicant: The Boeing Company, Chicago, IL (US)

(72) Inventor: Christopher M. Fetzer, Los Angeles, CA (US)

(21) Appl. No.: 15/361,121

(22) Filed: Nov. 25, 2016

(51) Int. Cl. H01G 9/20; H01S 5/36; H01L 51/42; H01L 51/50; H01L 51/56; H01L 51/00

(52) U.S. Cl. CPC H01G 9/2009; H01S 5/36; H01G 9/2018; H01L 51/4213; H01L 2031/0344; H01L 51/56; H01L 51/0002; H01L 51/0077; H01L 2251/558; H01L 51/5012

(57) ABSTRACT

A semiconductor device includes a semiconductor substrate and at least one perovskite layer disposed on the substrate. The semiconductor substrate includes a single-crystal semiconductor and the at least one perovskite layer includes a single-crystal organometallic-halide ionic solid perovskite.

### TECHNICAL FIELD

The subject matter described herein relates generally to semiconductor devices, specifically, optoelectronic semiconductor structures.

### BACKGROUND

Some optoelectronic devices include perovskite layers. These layers are typically amorphous, resulting from fabrication by one of two methods that include vapor conversion of nuclei or co-deposition of precursors to form perovskite layers on a substrate, such as a polycrystalline layer on glass (typically TiO2, FTO, or ITO). Even in the case of formation on layers or substrates comprising single crystals of, for example, TiO2, the resulting perovskites formed thereon are polycrystalline in nature. While not limited to any particular theory, it is believed that this is due, in part, to such single crystals having tetragonal, orthorhombic or monoclinic crystal structures (i.e., structures that are not cubic) having lattice constants that are not compatible with the quasi-cubic lattice constant of perovskites, such as methylammonium lead iodide (CH₃NH₃PbI₃). Accordingly, where the formation energy of a single crystalline layer of such quasi-cubic-structured perovskites is not favorable to the formation of many small grains, the formation energy of a polycrystalline perovskite thin-film layer comprising varying grain sizes is energetically favored when fabricated on a material having a non-cubic crystal structure.

Nonetheless, amorphous perovskite layers having thicknesses of about 100 nm to 1000 nm can be used as highly efficient semiconductor active layers in devices. However, perovskite active layers formed by conventional methods also suffer from limitations such as humidity degradation of the perovskite layer, hysteresis of light intensity-current-voltage (LIV) curve trace, temperature instability, and UV instability. While the root cause of these issues is the subject of current research, it is believed that the grain boundaries between device layers provide fast pathways for dissolution of the perovskite crystal and fast water diffusion pathways leading to intercalation or dissociation of the oxide layers that may underlie the polycrystalline perovskite active layer. Due to this degradation at grain boundaries, the use of amorphous perovskite active layers for optoelectronics devices is limited.

One method that has succeeded in producing stable perovskite active material is inverse temperature crystallization of single crystal perovskite layers. However, single crystal formation limits the device fabrication methods that require significant handling, cutting and polishing to produce devices. Further, single crystal perovskites are still small and difficult to produce. Improved epitaxial, single-crystal perovskites and methods for making the same would be welcome additions to the art.

### SUMMARY

A semiconductor device comprises a substrate comprising a single-crystal semiconductor; and at least one layer disposed on the substrate, wherein the at least one layer comprises an organometallic-halide ionic solid perovskite.

A method for making a semiconductor device, comprises: forming at least one perovskite layer on a substrate, wherein the substrate comprises a single-crystal semiconductor and the at least one perovskite layer comprises an organometallic-halide ionic solid perovskite; forming a first electrical contact in electrical communication with the substrate, the at least one perovskite layer or both; and forming a second electrical contact in electrical communication with the substrate, the at least one perovskite layer, or both.

While not limited to any particular theory it is believed that lattice matching between single crystal perovskites and underlying single crystal layers, such as the semiconductor substrate leads to a bandgap alignment and reduced resistivity between the perovskite layer and the and underlying single crystal layer. Other advantages of the examples will be set forth in part in the description which follows, and in part will be understood from the description, or may be learned by practice of the examples. The advantages will be realized and attained by means of the elements and combinations particularly pointed out in the appended claims. The materials used for the semiconductor layer and the materials used for the perovskite layers described herein can be lattice matched, thereby leading to enhanced electrical properties and increased device efficiencies.

It is to be understood that both the foregoing general description and the following detailed description are exemplary and explanatory only and are not restrictive of the examples, as claimed.

### BRIEF DESCRIPTION OF THE DRAWINGS

The accompanying drawings, which are incorporated in and constitute a part of this specification, illustrate examples of the present teachings and together with the description, serve to explain the principles of the disclosure.

FIG. 1A is an illustration of an organic-metal halide perovskite quasi-cubic unit cell.

FIG. 1B is an illustration of an organic-metal halide quasi-cubic perovskite crystal structure.

FIG. 1C is an illustration of a simplified octahedron representation of the unit cell of FIG. 1A.

FIG. 2A is an illustration depicting a cross-sectional view of a semiconductor device according to an implementation, including a magnified representation of the crystal structure of adjacent layers of the device according to an implementation.

FIG. 2B is an illustration depicting a top view of a magnified representation of the crystal structure shown in the inset of FIG. 2A.

FIG. 2C is an illustration depicting a magnified representation of the crystal structure of adjacent layers of the device of FIG. 2A according to an alternate implementation.

FIG. 2D is an illustration depicting a top view of a magnified representation of the crystal structure shown in the inset of FIG. 2C.

FIG. 3 is a flow chart depicting a method for forming a semiconductor device according to an implementation.

### DETAILED DESCRIPTION

Reference will now be made in detail to the examples which are illustrated in the accompanying drawings. Wherever possible, the same reference numbers will be used throughout the drawings to refer to the same or like parts.

Notwithstanding that the numerical ranges and parameters setting forth the broad scope of the examples are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less that 10” can assume negative values, e.g. −1, −2, −3, −10, −20, −30, etc.

Further, one or more of the acts depicted herein may be carried out in one or more separate acts and/or phases. Furthermore, to the extent that the terms “including,” “includes,” “having,” “has,” “with,” or variants thereof are used in either the detailed description and the claims, such terms are intended to be inclusive in a manner similar to the term “comprising.” Additionally, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “at least one of” is used to mean one or more of the listed items may be selected. As used herein, the phrase “one or more of”, for example, A, B, and C means any of the following: either A, B, or C alone; or combinations of two, such as A and B, B and C, and A and C; or combinations of three A, B, and C.

The following examples are described for illustrative purposes only with reference to the Figures. Those of skill in the art will appreciate that the following description is exemplary in nature, and that various modifications to the parameters set forth herein could be made without departing from the scope of the present examples. It is intended that the specification and examples be considered as exemplary only. The various examples are not necessarily mutually exclusive, as some examples can be combined with one or more other examples to form new examples. It will be understood that the structures depicted in the figures may include additional features not depicted for simplicity, while depicted structures may be removed or modified.

Generally described herein are optoelectronic devices that include at least one epitaxially grown perovskite material layer, as opposed to amorphous or polycrystalline perovskite layers that suffer from limitations such as humidity degradation temperature instability, and UV instability, and corresponding methods for growing the at least one perovskite material layer, for example, on a semiconductor substrate. To overcome issues associated with amorphous or polycrystalline perovskites as described above, a method for single crystal perovskite fabrication includes forming an epitaxial single layer of the perovskite on a single crystal semiconductor substrate. That is, by selection of a single crystal semiconductor substrate having a lattice constant that is compatible with the quasi-cubic lattice constant of perovskites, the formation energy of such quasi-cubic-structured perovskites as a single crystalline layer is energetically favored when fabricated epitaxially on a substrate having a lattice matched crystal structure.

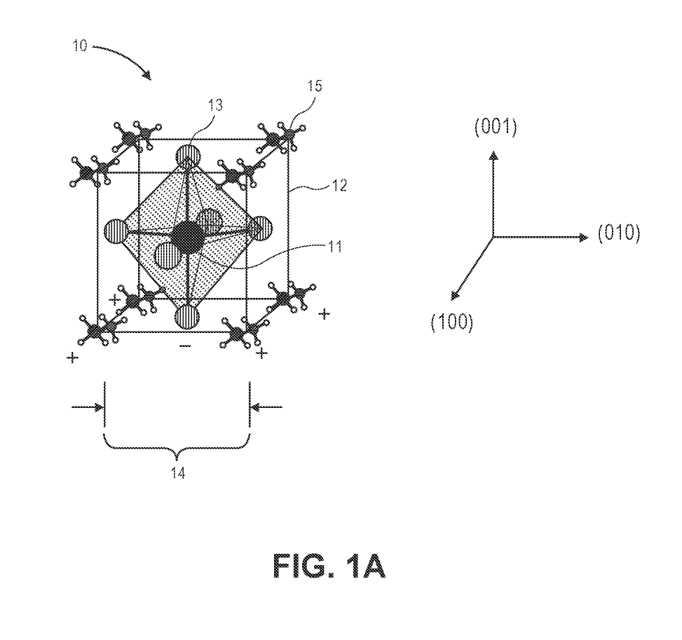

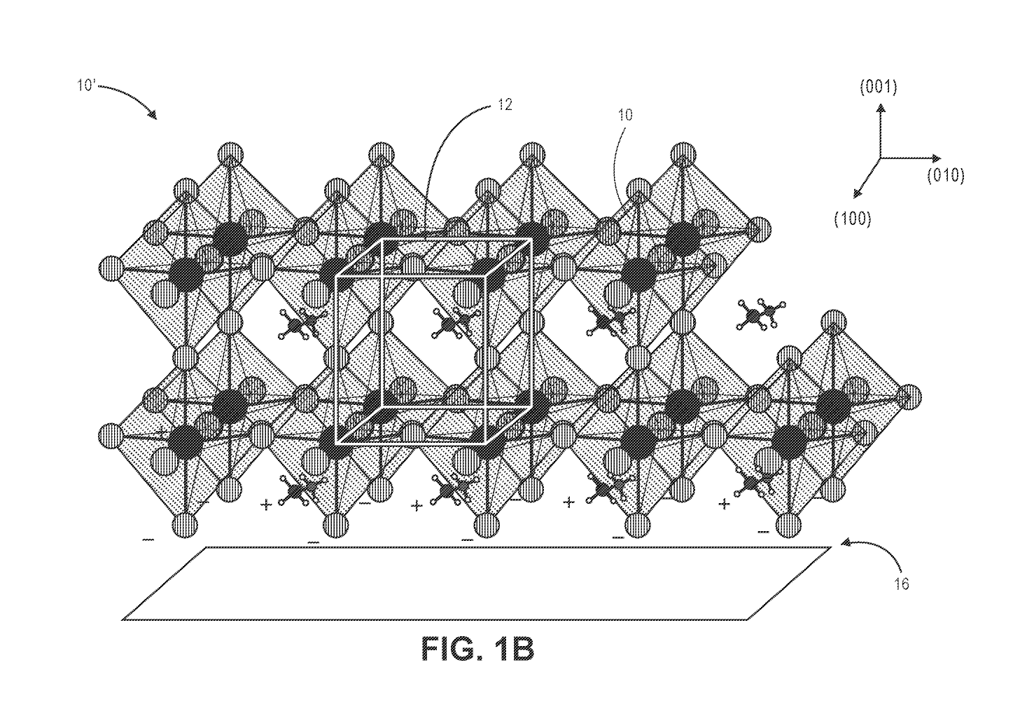

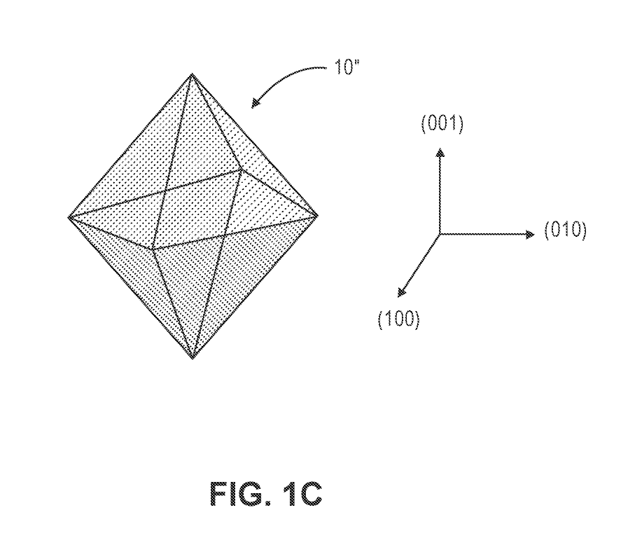

FIG. 1A is an illustration of an organometallic halide ionic solid perovskite 10. The organometallic halide ionic perovskite includes group IV ion 11, negatively charged halide ions 13, and positively charged organic ions 15 and its quasi-cubic unit cell 12 has a corresponding perovskite lattice space in lattice constant 14. In FIG. 1B, a plurality of the unit cells are shown together as the quasi-cubic organometallic halide ionic solid perovskite crystal structure 10′ (referred to hereinafter as “quasi-cubic perovskite crystal structure 10′”) having a quasi-cubic unit cell 12. For the sake of crystallographic orientation, the quasi-cubic perovskite crystal structure 10′ is shown above a (001) plane 16. FIG. 1C includes a simplified representation of the organometallic halide ionic solid perovskite 10 of FIG. 1A shown as octahedron 10″.

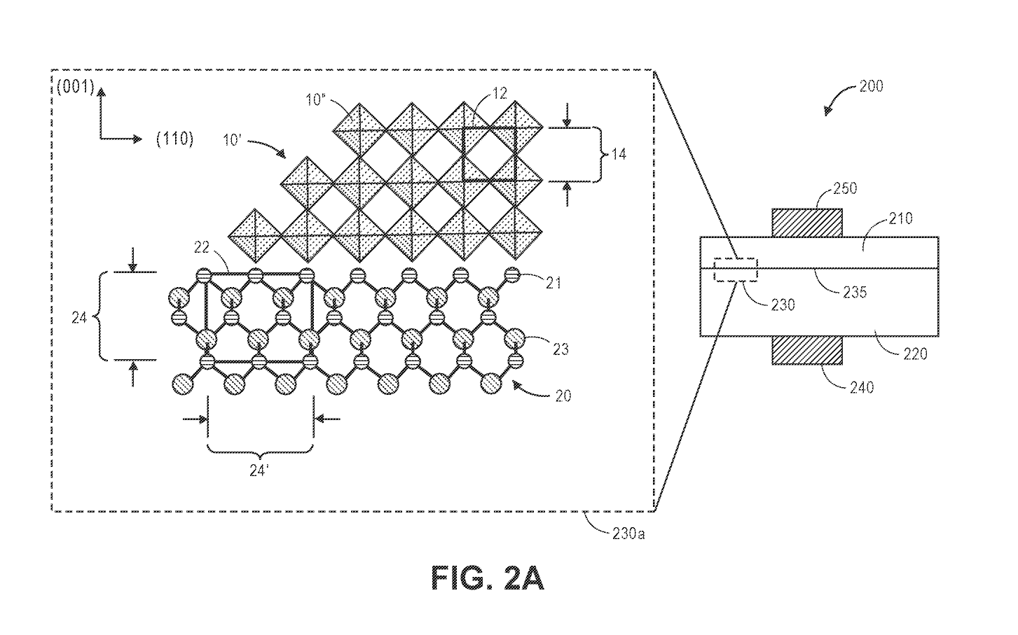

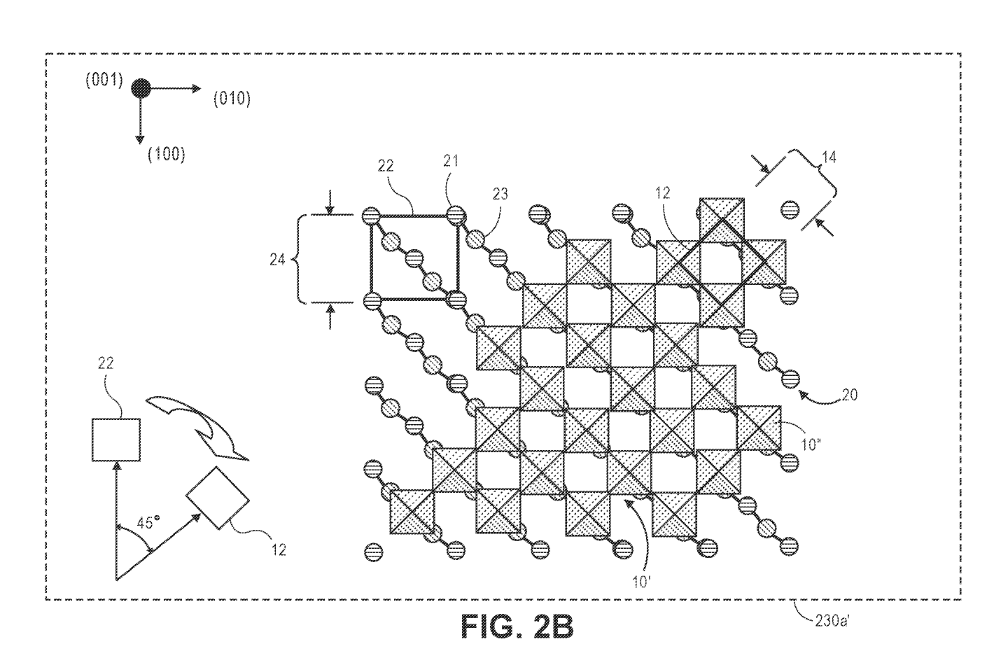

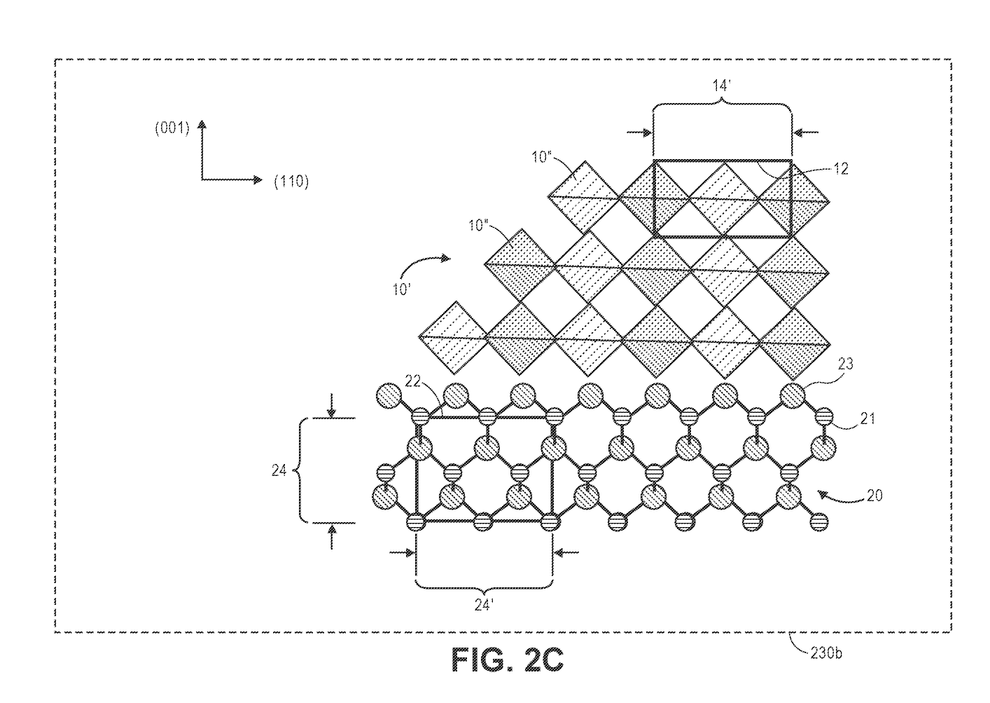

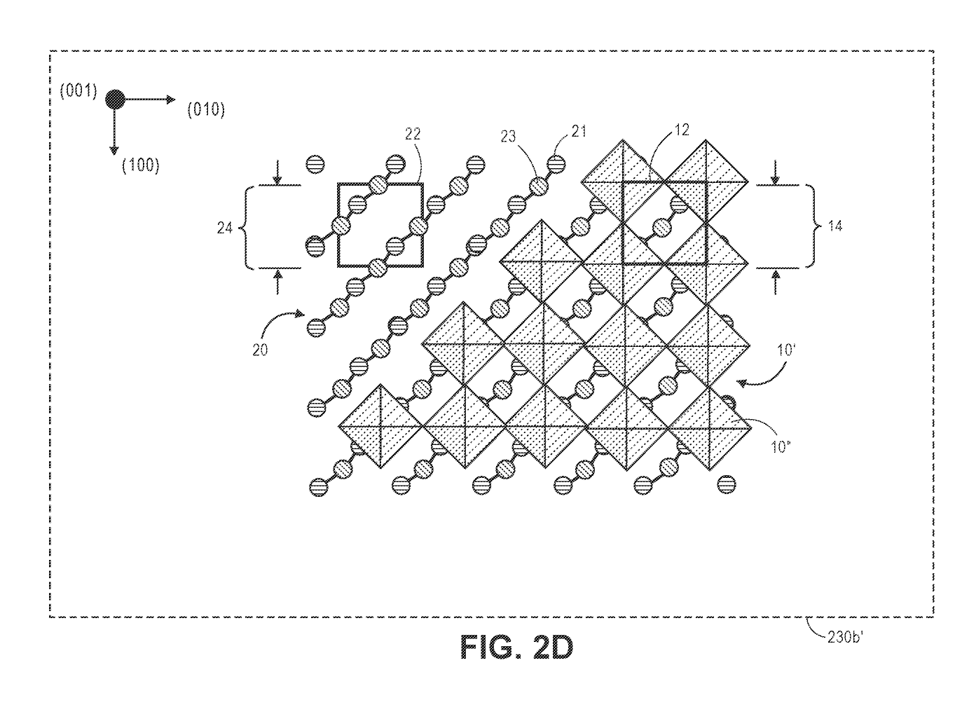

In an example, a semiconductor device comprises: a semiconductor substrate and at least one perovskite layer disposed on the substrate. The semiconductor substrate comprises a single-crystal semiconductor and the at least one perovskite layer comprises a single-crystal organometallic-halide ionic solid perovskite. In one implementation, FIG. 2A depicts a cross-sectional view of a semiconductor device 200. Generally, the semiconductor device 200 includes at least one perovskite layer 210 disposed over a semiconductor substrate 220, such as on a surface 235 of the semiconductor substrate 220. The semiconductor device 200 further includes a first electrode 240 that is disposed on a first surface of the device, such as on the semiconductor substrate 220, and a second electrode 250 that is disposed on a second surface of the device, such as on the perovskite layer 210. The first electrode 240 and second electrode may each be configured to be in electrical communication the substrate, the at least one perovskite layer and/or each other. Accordingly, the semiconductor device may comprise an optoelectronic device, for example, a light emitting diode (LED), a laser diode, or a solar cell.

As described in more detail below, the semiconductor substrate 220 comprises a single-crystal semiconductor with a corresponding semiconductor crystal structure 20. The substrate single-crystal semiconductor may be configured as a polar crystal (e.g., in the case of a III-V semiconductor, polarized with surface group III atoms that are slightly positively charged respect to negative group V atoms). The semiconductor substrate 220 may be purchased or may be fabricated by known methods.

The perovskite layer 210 comprises a single crystal perovskite, such as an organometallic-halide ionic solid perovskite, that has a corresponding quasi-cubic perovskite crystal structure 10′. As described above for FIG. 1B, the quasi-cubic perovskite crystal structure 10′ of the perovskite layer 210 is comprised, in part, of positively charged organic molecules and negatively charged halide atoms. As such, returning to FIG. 2A, the perovskite layer 210 may itself be polar-aligned with the substrate 220 (i.e., negative halide ions align with positively charged atoms of the semiconductor substrate). The perovskite layer 210 may be formed via any method that leads to formation of the quasi-cubic perovskite crystal structure 10′ as a single crystal. Such a method may be any epitaxial deposition method currently known, such as inverse temperature crystallization, or developed in the future so long as the resulting quasi-cubic perovskite crystal structure 10′ is formed as a single crystal. Additionally, as an ionic solid, the single crystal organometallic halide ionic solid perovskite has a corresponding quasi-cubic perovskite crystal structure 10′ that exhibits a slightly polar nature in its bonding which makes it an advantageous candidate for epitaxial growth on, for example, the single-crystal semiconductor substrate having a polar crystal structure. For example, the ionic cores of the perovskite layer 210 exhibits a polar alignment with the underlying semiconductor substrate 220 comprising the single-crystal semiconductor.

As discussed above, the formation energy of a single crystalline layer, such as that for perovskite layer 210, is not favorable to the formation of many small crystalline grains such as those of a polycrystalline perovskite layer. Therefore, in order to reproduce the lattice spacing represented by lattice constant 24, 24′ of the semiconductor crystal structure 20 without forming multiple nuclei of the epitaxial layer material (which would lead to a polycrystalline layer instead of a single crystal), there must also be an epitaxial relationship between the quasi-cubic perovskite crystal structure 10′ of the perovskite layer 210 and semiconductor crystal structure 20 of the semiconductor substrate 220. That is, the perovskite material selected for epitaxial growth must be capable of forming a quasi-cubic perovskite crystal structure 10′ that has a lattice constant similar to the lattice constant of the underlying substrate's semiconductor crystal structure 20. In other words, the lattice mismatch between the quasi-cubic perovskite crystal structure 10′ and the semiconductor crystal structure 20 must not be too large. That is, the quasi-cubic perovskite crystal structure 10′ and the semiconductor crystal structure 20 are substantially lattice matched. In an example, the lattice mismatch between the quasi-cubic perovskite crystal structure 10′ and the semiconductor crystal structure 20 may be less than or equal to about 17%, such as less than or equal to about 8%, including less than or equal to about 5%, such as less than or equal to about 3%. Accordingly, as used here, the phrase “substantially lattice matched” includes a lattice mismatch between the quasi-cubic perovskite crystal structure 10′ and the semiconductor crystal structure 20 of less than or equal to about 17%, such as less than or equal to about 8%, including less than or equal to 5%, such as less than or equal to about 3%.

The perovskite layer 210 may comprise an organometallic halide ionic solid perovskite, for example, a single-crystal organometallic-halide ionic solid perovskite. In an example, the organometallic halide ionic solid perovskite comprises an epitaxially grown single crystal. Generally, the organometallic halide ionic solid perovskite may be represented by the formula, ABX₃, where A comprises an organic ion, B comprises a group-IV ion, and X comprises a halide ion. The organic ion may comprise methylammonium (MA), formamidine (FA), at least one alkali metal, or combinations thereof, wherein the alkali metal may comprise cesium (Cs), rubidium (Rb) or both. The group-IV ion may comprise Pb⁺, Sn⁺, or a combination thereof and the halide ion may comprise Br, P, or combinations thereof. In an example, the organometallic halide ionic solid perovskite comprises methylammonium lead iodide (CH₃NH₃PbI₃), methylammonium lead bromide (CH₃NH₃PbBr₃), methylammonium lead chloride (CH₃NH₃PbCl₃), methylammonium tin bromide (CH₃NH₃SnI₃), methylammonium tin bromide (CH₃NH₃SnBr₃), formamidinium lead iodide (NH₂CH═NH₂PbI₃), or mixtures thereof.

In order to be substantially lattice matched to an underlying semiconductor substrate so as to be, for example, capable of epitaxially growing as a single crystal, exemplary organometallic halide ionic solid perovskites can include those having quasi-cubic lattice constant (aₚₑᵣₒᵥₛₖᵢₜₑ) of between 5.2 Å to about 6.6 Å, or for example, between about 5.6 Å to about 6.4 Å, including between about 5.6 Å to about 5.8 Å, between about 5.8 Å to about 6.0 Å, or between about 6.0 Å to about 6.4 Å. As used herein the term “quasi-cubic lattice constant” refers to a non-directional average of all of the lattice constant dimensions of semiconductors having multiple crystallographic forms (e.g., in the case of III-V structures, cubic and hexagonal). Additionally, the at least one perovskite layer may comprise more than one perovskite layer stacked, one over the other, either on one another or with one or more intervening layers between each of the more than one perovskite layers. In an implementation, the at least one perovskite layer may comprise a thickness of equal to or less than about 10 microns, for example, in order to serve as the active layer in a semiconductor device.

The semiconductor substrate 220 comprises a material having a crystal structure similar to that of the perovskite's crystal structure. That is, the semiconductor substrate may comprise a semiconductor crystal structure having a cubic or hexagonal lattice constant (a_{substrate}) of between 5.2 Å to about 6.6 Å, or for example, between about 5.3 Å to about 6.5 Å, including between about 5.3 Å to about 5.5 Å, between about 5.6 Å to about 5.7 Å, between about 5.8 Å to about 6.0 Å, or between about 6.4 Å to about 6.5 Å. As discussed above with respect to FIG. 1B, the quasi-cubic perovskite crystal structure 10′ has a quasi-cubic unit cell 12. Accordingly, the semiconductor substrate 220 comprises a single crystal having a cubic or hexagonal crystal structure. Exemplary semiconductor materials for the semiconductor substrate 220 may comprise a group III-V semiconductor, such as a group III-V compound semiconductor, for example, comprising AlP, GaP, GaInP, GaAs, InGaAs, InAs, InP, or mixtures thereof; a group IV semiconductor such as that comprising C, Si, Pb, Ge, Sn, or mixtures thereof; a group IV-VI compound semiconductor such as PbS, PbTe and Pb Se; a group II-VI semiconductor, such as a II-VI compound semiconductor, for example, ZnS, ZnSe, ZnTe, CdS, CdSe, CdTe, HgS, HgSe, HgTe, or mixtures thereof; compound semiconductors such as those comprising mixtures of group II, III, IV, V, VI atoms; or a single-crystal perovskite that may also comprise an organometallic halide ionic solid perovskite represented by the formula, ABX₃, but wherein at least one of A, B or X is different than that of the organometallic halide ionic solid perovskite of perovskite layer 210 (e.g., a perovskite layer 210 comprising MAPbCl₃ may be epitaxially grown on a semiconductor substrate comprising MAPbI₃ or vice versa, for example, in order to be substantially lattice matched with one another while also having similar crystal structures as well as different bandgaps). The semiconductor substrate 220 may be provided by purchase or by preparing according to standard substrate processing methods known in the art. In an example, the semiconductor substrate may comprise a perovskite crystal substrate, such as an oxide perovskite crystal substrate, for example, CaTiO₃, SrTiO₃ or MgSiO₃, each of which may be retained from their naturally occurring mineral forms or may be manufactured (e.g., strontium titinate CAS # 1206-05-9 available from MTI Corporation of Richmond, Calif.). The semiconductor substrate may be selected to survive increased temperature, for example in the range of about 100° C. to about 400° C., or the crystallization temperature (Tc), or the temperature at which precipitation of the epitaxial layer occurs, such that it is not detrimentally affected by solvent materials of a solution from which the perovskite layer 210 is epitaxially formed, i.e., such that the substrate does not dissolve during the epitaxial growth of the perovskite layer 210 in a liquid transport epitaxial process.

The first and second electrodes may be any conductive material capable of forming an ohmic contact with the perovskite of the at least one perovskite layer 210 and with the semiconductor substrate 220. Exemplary electrode materials include metals such as Al and Ag; metal alloys such as AlAg, carbon-based ohmic contacts, conductive oxides such as indium tin oxide (ITO) or fluorine-doped tin oxide (SnO₂:F); or mixtures thereof. The first and second electrodes may be formed according to standard electrode processing methods known in the art.

A first implementation of the polar alignment in the quasi-cubic perovskite crystal structure 10′ and the epitaxial relationship between quasi-cubic perovskite crystal structure 10′ and semiconductor crystal structure 20 are visualized in the (110) edge-on view 230a of the inset 230 in FIG. 2A. Here, the quasi-cubic perovskite crystal structure 10′ of the perovskite layer 210 is shown disposed on semiconductor substrate 220 comprising semiconductor crystal structure 20 which includes a plurality of first atoms 21, each bonded to a corresponding one of and a plurality of second atoms 23. In an example, the semiconductor substrate comprises a group III-terminated, III-V compound semiconductor, wherein the plurality of first atoms 21 are group III atoms and the plurality of second atoms 23 are group V atoms (e.g., a top surface of the semiconductor substrate 220 is group-III terminated). In such an example, the quasi-cubic perovskite crystal structure 10′ is disposed on a group III-terminated, III-V (001) surface of the semiconductor substrate 220 having semiconductor crystal structure 20. The group III-terminated, III-V (001) surface of the semiconductor may be undimerized. In other words, the surface can include undimerized surface atoms which have no upper nearest-neighbor atoms and are not bonded to one another. Accordingly, the III-V semiconductor substrate having semiconductor crystal structure 20 is polarized with surface group-III first atoms 21, which are slightly positively charged with respect to the negatively charged group V second atoms 23. Thus, the negatively charged halide ions 13 of the organometallic halide ionic solid perovskite 10 (shown as simplified octahedron 10″) align with the group III first atoms 21 of the semiconductor substrate. It is noted that although in this example, the semiconductor substrate 220 is represented as a group III-terminated, III-V compound semiconductor comprised of group III first atoms 21 and group V second atoms 23, other materials described for the semiconductor substrate 220 may instead be represented by semiconductor crystal structure 20 comprised of the first atoms 21 and second atoms 23. Thus, in some examples, first atoms 21 may comprise group II, group III, or group IV atoms. Also, in some examples, second atoms 23 may comprise group IV, group V, or group VI atoms. Accordingly, in some examples, first atoms 21 and second atoms 23 may comprise the same type or different type of atom. In some examples, the substrate may comprise a top surface that is group-II terminated, a group-III terminated, and/or group-IV terminated.

In addition to being polar-aligned with the surface of the semiconductor substrate 220's semiconductor crystal structure 20, as described above with respect to FIG. 2A, the quasi-cubic, quasi-cubic perovskite crystal structure 10′ of the perovskite layer 210 can have a corresponding crystallographic orientation. This crystallographic orientation is relative to the semiconductor crystal structure 20 of the underlying semiconductor substrate 220. For example, top view 230a′ in FIG. 2B depicts a top view of the magnified representation of the edge-on view 230a of FIG. 2A. In top view 230a′, a crystallographic relationship between quasi-cubic perovskite crystal structure 10′ and semiconductor crystal structure 20 is shown. Here, quasi-cubic unit cell 12 of the quasi-cubic perovskite crystal structure 10′ is rotated 45-degrees in plane from the unit cell 22 of the substrate's semiconductor crystal structure 20. Accordingly, the lattice constant 14 (i.e., aₚₑᵣₒᵥₛₖᵢₜₑ) of the quasi-cubic perovskite crystal structure 10′ of perovskite layer 210 and the lattice constant 24 (i.e., a_{substrate}) of the semiconductor crystal structure 20 of semiconductor substrate 220, are substantially lattice matched as shown in FIGS. 2A-2B, and lattice constant 24′ has a value of √2*a_{substrate} (i.e., the square root of two multiplied by a_{substrate}).

A second implementation of the polar alignment in the quasi-cubic perovskite crystal structure 10′ and the epitaxial relationship between quasi-cubic perovskite crystal structure 10′ and semiconductor crystal structure 20 are visualized in the (110) edge-on view 230b in FIG. 2C for the inset 230 of FIG. 2A. Here, the quasi-cubic perovskite crystal structure 10′ of the perovskite layer 210 is shown disposed on semiconductor substrate 220 comprising semiconductor crystal structure 20 which includes a plurality of first atoms 21, each bonded to a corresponding one of and a plurality of second atoms 23. In an example, the semiconductor substrate comprises a group V-terminated III-V compound semiconductor, wherein the plurality of first atoms 21 are group III atoms and the plurality of second atoms 23 are group V atoms. Accordingly, in such an example, the quasi-cubic perovskite crystal structure 10′ is disposed on an undimerized, group V-terminated, III-V (001) surface of the semiconductor substrate 220 crystal structure 20. Here, the III-V semiconductor having semiconductor crystal structure 20 is polarized with surface group V atoms 23 which are slightly negatively charged with respect to the positively charged group III atoms 21. Thus, the positively charged organic ions 15 of organometallic halide ionic solid perovskite 10 (which are not shown in the simplified octahedron 10″ in FIG. 2C) align with the group V atoms 21. It is noted that although in this example, the semiconductor substrate 220 is represented as a group III-terminated, III-V compound semiconductor comprised of group III first atoms 21 and group V second atoms 23, other materials described for the semiconductor substrate 220 may instead be represented by structure 20 comprised of the first atoms 21 and second atoms 23. Thus, in some examples, first atoms 21 may comprise group II, group III or group IV atoms. Also, in some examples, second atoms 23 may comprise group IV, group V or group VI atoms. Accordingly, in some examples, first atoms 21 and second atoms 23 may comprise the same type of atom, as with a group IV semiconductor, or different type of atom as in a compound semiconductor. In some examples, the substrate may comprise a top surface that is group-IV terminated, a group-V terminated, or both a group-VI and a group-V terminated top surface.

In addition to being polar-aligned with the surface of the semiconductor substrate 220 semiconductor crystal structure 20, as described in the example above for the group V-terminated, III-V compound semiconductor as shown in FIGS. 2C, the quasi-cubic perovskite crystal structure 10′ of the perovskite layer 210 comprising, for example, an organometallic-halide ionic solid perovskite, can have a corresponding crystallographic orientation relative to the crystal structure of the underlying semiconductor substrate 220. For example, top view 230b′ in FIG. 2D depicts a top view of the magnified representation of the edge-on view 230b of FIG. 2C. In top view 230b′, a crystallographic relationship between quasi-cubic perovskite crystal structure 10′ and semiconductor crystal structure 20 is shown. Here, unit cell 12 of the organometallic-halide ionic solid perovskite's quasi-cubic lattice of quasi-cubic perovskite crystal structure 10′ is not rotated in plane from the unit cell 22 of the substrate's cubic lattice of semiconductor crystal structure 20. Accordingly, the lattice constants 14 (i.e., aₚₑᵣₒᵥ) and lattice constants 14′ (i.e., √2*aₚₑᵣₒᵥₛₖᵢₜₑ) of the quasi-cubic perovskite crystal structure 10′ of perovskite layer 210 are substantially lattice matched with respect to the lattice constants 24 (i.e., a_{substrate}) and lattice constant 24′ (i.e., √2*a_{substrate,}) of the semiconductor crystal structure 20 of semiconductor substrate 220, respectively as shown in FIGS. 2C-2D.

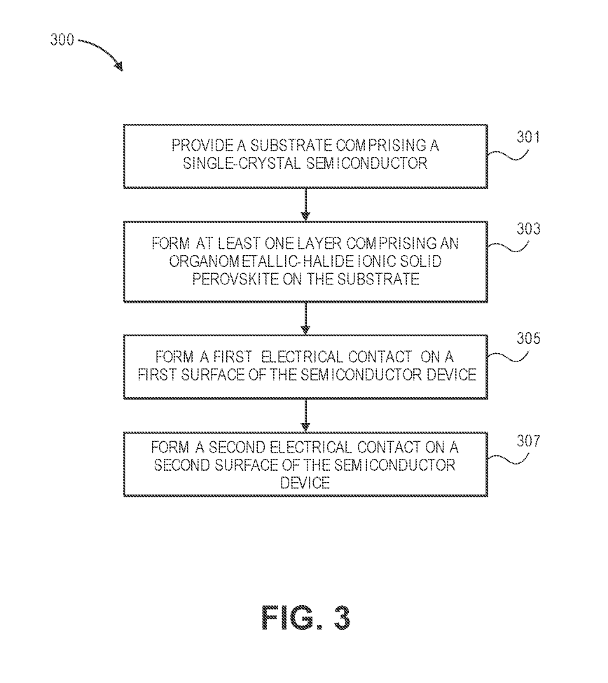

FIG. 3 is a flow chart depicting a method 300 for forming a semiconductor device, such as semiconductor device 200 of FIG. 2A. In an implementation, the method 300 comprises providing a substrate comprising a single-crystal semiconductor at 301 and forming at least one perovskite layer comprising an organometallic-halide ionic solid perovskite on the substrate at 303. The method 300 also comprises forming a first electrical contact at 305. Generally, the first electrical contact may be formed on a first surface of the semiconductor device. More specifically, the first electrical contact may be formed in electrical communication with the substrate, the at least one perovskite layer or both. The method 300 also comprises forming a second electrical contact at 307. Generally, the second electrical contact may be formed on a second surface of the semiconductor device. More specifically, the first electrical contact may be formed in electrical communication with the substrate, the at least one perovskite layer, or both. In the method 300, the substrate comprising a single-crystal semiconductor may comprise any of the materials described above and may be formed according to the methods described above with respect to semiconductor substrate 220. In the method 300, the at least one perovskite layer may comprise any of the materials described above and may be formed according to the methods described above with respect to perovskite layer 210. For example, the forming of the at least one perovskite layer at 303 may be implemented via inverse temperature crystallization. However, while in some of the examples described above the perovskite layer 210 is formed via a liquid transport epitaxial process, implementations of method 300 for making a semiconductor device as described in FIG. 3 are not so limited, and forming of the at least one perovskite layer may instead be executed in a vapor-phased based epitaxial process.

While the examples have been illustrated respect to one or more implementations, alterations and/or modifications can be made to the illustrated examples without departing from the spirit and scope of the appended claims. In addition, while a particular feature of the examples may have been disclosed with respect to only one of several implementations, such feature may be combined with one or more other features of the other implementations as may be desired and advantageous for any given or particular function.

Other examples will be apparent to those skilled in the art from consideration of the specification and practice of the descriptions disclosed herein. It is intended that the specification and examples be considered as exemplary only, with a true scope and spirit of the examples being indicated by the following claims.

What is claimed is:

1. A semiconductor device, comprising:
a substrate comprising a single-crystal semiconductor; and
at least one perovskite layer disposed on the substrate, wherein the at least one perovskite layer comprises a single-crystal organometallic-halide ionic solid perovskite disposed on the substrate.

2. The semiconductor device of claim 1 further comprising a first electrical contact and a second electrical contact to be in electrical communication with the substrate, the at least one perovskite layer, or both.

3. The semiconductor device of claim 1, wherein single-crystal organometallic-halide ionic solid perovskite comprises an epitaxially grown single crystal.

4. The semiconductor device of claim 3 further comprising a lattice mismatch of about 5% or less between a crystal structure of the single-crystal semiconductor and a crystal structure of the single-crystal organometallic-halide ionic solid perovskite.

5. The semiconductor device of claim 1, wherein the at least one perovskite layer comprises a thickness of equal to or less than about 10 microns.

6. The semiconductor device of claim 1, wherein the single-crystal organometallic halide ionic solid perovskite is represented by the formula, ABX₃, where A comprises methylammonium (MA), formamidine (FA), cesium (Cs), rubidium (Rb), or a combination thereof; B comprises Pb, Sn, or a combination thereof; and X comprises a halide such as Cl, Br, I, or a combinations thereof.

7. The semiconductor device of claim 1, wherein the single-crystal organometallic halide ionic solid perovskite comprises methylammonium lead iodide (CH₃NH₃PbI₃).

8. The semiconductor device of claim 1, wherein the substrate comprises a group III-V semiconductor, a group II-VI semiconductor, a group IV-VI semiconductor, or a group IV semiconductor.

9. The semiconductor device of claim 8, wherein the group III-V semiconductor comprises GaInP, GaAs, InGaAs, InAs, InP, or mixtures thereof.

10. The semiconductor device of claim 9, wherein a top surface of substrate is group-III terminated.

11. The semiconductor device of claim 9, wherein a top surface of the substrate is group-V terminated.

12. The semiconductor device of claim 8, wherein the group II-VI comprises ZnS, ZnSe, ZnTe, CdS, CdSe, CdTe, HgS, HgSe, HgTe, or mixtures thereof

13. The semiconductor device of claim 12, wherein a top surface of the substrate is group-II terminated.

14. The semiconductor device of claim 12, wherein a top surface of the substrate is group-VI terminated.

15. The semiconductor device of claim 8, wherein the group IV semiconductor comprises C, Si, Ge, Sn, or mixtures thereof.

16. The semiconductor device of claim 1, wherein the substrate comprises a cubic crystal lattice and the single-crystal organometallic-halide ionic solid perovskite comprises a quasi-cubic crystal lattice.

17. The semiconductor device of claim 16, wherein a unit cell of the single-crystal organometallic-halide ionic solid perovskite's quasi-cubic crystal lattice is rotated 45-degrees in plane from a unit cell of the substrate's cubic crystal lattice.

18. The semiconductor device of claim 1, wherein the single-crystal semiconductor comprises a first organometallic-halide ionic solid perovskite, the at least one perovskite layer comprises a second organometallic-halide ionic solid perovskite, and wherein the first organometallic-halide ionic solid perovskite is different than the second organometallic-halide ionic solid perovskite.

19. A method for making a semiconductor device, comprising:
forming at least one perovskite layer on a substrate, wherein the substrate comprises a single-crystal semiconductor and wherein the at least one perovskite layer comprises a single-crystal organometallic-halide ionic solid perovskite; and
forming a first electrical contact in electrical communication with the substrate, the at least one perovskite layer or both; and
forming a second electrical contact in electrical communication with the substrate, the at least one perovskite layer, or both.

20. The method of claim 19, wherein the forming of the at least one perovskite layer comprises epitaxially growing the at least one perovskite layer.

21. The method of claim 20, wherein the epitaxially growing comprises forming a lattice mismatch of about 5% or less between a crystal structure of the single-crystal semiconductor and a crystal structure of the single-crystal organometallic-halide ionic solid perovskite.

22. The method of claim 19, wherein the substrate comprises a cubic crystal lattice and wherein the organometallic-halide ionic solid perovskite semiconductor comprises a quasi-cubic crystal lattice.

23. The method of claim 19, wherein the substrate comprises a cubic crystal lattice defining a unit cell, wherein the at least one perovskite layer comprises a quasi-cubic crystal lattice defining a unit cell, and wherein the unit cell of the organometallic-halide ionic solid perovskite semiconductor's cubic crystal lattice is rotated 45-degrees in-plane from the unit cell of the semiconductor substrate's cubic crystal lattice.
